(19) United States
(12) Patent Application Publication
(10) Pub. No.: US 2016/0132388 A1
(43) Pub. Date: May 12, 2016

(54) SEMICONDUCTOR MEMORY DEVICE AND ECC METHOD THEREOF

(71) Applicant: SAMSUNG ELECTRONICS CO., LTD, Yeibgtib-dong,Gyeonggi-do (KR)

(72) Inventor: BoGeun KIM, Suwon-si (KR)

(21) Appl. No.: 14/895,819

(22) PCT Filed: Jun. 14, 2013
(86) PCT No.: PCT/IB2013/054868

§ 371 Date: Dec. 3, 2015

(51) Int. Cl. G06F 11/10; G11C 29/52; G06F 3/06

(52) U.S. Cl. CPC G06F 11/1068; G06F 3/0619; G06F 3/0688; G11C 29/52; G06F 3/064

(57) ABSTRACT

A semiconductor memory device and ECC method thereof are provided which a first nonvolatile memory; a second nonvolatile memory having a type different from the first nonvolatile memory; a controller; a first error correction circuit configured to correct an error of first write data to be programmed at the first nonvolatile memory; and a second error correction circuit included in the controller and configured to correct an error of first write data or an error of second write data to be programmed at the second nonvolatile memory, based on an error correction algorithm different from that of the first error correction circuit. Error correction data for correcting an error of the first write data is generated using one of the first error correction circuit and the second error correction circuit according to an attribute of the first write data.

### BACKGROUND

The inventive concepts described herein relate to a semiconductor memory device including different types of nonvolatile memories.

A semiconductor memory device may be volatile or nonvolatile. A volatile memory device may have rapid read and write speeds, while contents stored in the volatile memory device may be lost at power-off. On the other hand, a nonvolatile memory device may retain contents stored therein even at power-off. Thus, the nonvolatile memory device may be used to store contents which must be retained regardless of whether a power is supplied or not.

A flash memory device may be used at a handheld electronic device as a high-integration and large-volume nonvolatile semiconductor memory device. Also, a magnetic random access memory (hereinafter, referred to as an MRAM) may use a magnetic element as a nonvolatile element for random access, high integration and large volume. The MRAM may be advantageous for fast operating speed and high integration.

In recent years, there may have been proposed a semiconductor memory device which integratedly uses different types of nonvolatile memories (e.g., NAND flash memory, MRAM, etc.) to improve the performance of a nonvolatile semiconductor memory device. However, since different types of nonvolatile memories have different data storage manners and management manners, a demand on techniques for controlling different types of nonvolatile memories efficiently may increase.

### SUMMARY

One aspect of embodiments of the inventive concept is directed to provide a semiconductor memory device which comprises a first nonvolatile memory; a second nonvolatile memory having a type different from the first nonvolatile memory; a controller configured to control the first nonvolatile memory and the second nonvolatile memory; a first error correction circuit configured to correct an error of first write data to be programmed at the first nonvolatile memory; and a second error correction circuit included in the controller and configured to correct an error of first write data or an error of second write data to be programmed at the second nonvolatile memory, based on an error correction algorithm different from that of the first error correction circuit, wherein error correction data for correcting an error of the first write data is generated using one of the first error correction circuit and the second error correction circuit according to an attribute of the first write data.

In example embodiments, if the first write data has an attribute of meta data, the error correction data is generated using the first error correction circuit.

In example embodiments, if the first write data has an attribute of normal data, the error correction data is generated using the second error correction circuit.

In example embodiments, if the first write data has an attribute of buffer data, the error correction data is generated using the second error correction circuit, and the buffer data is data which is temporarily programmed at the first nonvolatile memory to write the buffer data at the second nonvolatile memory.

In example embodiments, the first error correction circuit is included in the first nonvolatile memory.

In example embodiments, the first error correction circuit is included in the controller.

In example embodiments, a program speed of the first nonvolatile memory is faster than that of the second nonvolatile memory.

In example embodiments, the first nonvolatile memory is a resistive memory reads a resistance value between both ends of a memory cell to decide data stored at the memory cell.

In example embodiments, the first nonvolatile memory is a magnetic random access memory.

In example embodiments, the second nonvolatile memory is a NAND flash memory.

In example embodiments, the first error correction circuit generates the error correction data according to an error correction algorithm using hamming code.

In example embodiments, the second error correction circuit generates the error correction data according to an error correction algorithm using a BCH code or an LDPC code.

Another aspect of embodiments of the inventive concept is directed to provide an ECC method of a semiconductor memory device which includes a first nonvolatile memory, a second nonvolatile memory having a type different from that of the first nonvolatile memory, and a controller to control the first nonvolatile memory and the second nonvolatile memory. The ECC method comprises determining an attribute of write data to be programmed at the first nonvolatile memory; generating error correction data for correcting an error of the write data using one of a first error correction circuit and a second error correction circuit according to an attribute of the write data and a type of the first nonvolatile memory; and storing the error correction data, wherein the first error correction circuit and the second error correction circuit generate the error correction data according to different error correction algorithms.

In example embodiments, the semiconductor memory device controls the controller such that error correction data for write data to be programmed at the second nonvolatile memory is generated using the second error correction circuit.

In example embodiments, the semiconductor memory device stores the error correction data at the first nonvolatile memory, the second nonvolatile memory or the controller.

According to embodiments of the inventive concept, a semiconductor memory device including different types of nonvolatile memories may be configured to correct an error of write data selectively using a part of a plurality of error correction circuits to which different error correction algorithms are applied according to an attribute of the write data and a type of nonvolatile memory at which the write data is to be programmed. Thus, error correction may be effectively performed by correcting an error using an error correction algorithm most suitable for an attribute of write data and a type of nonvolatile memory.

### BRIEF DESCRIPTION OF THE FIGURES

The above and other objects and features will become apparent from the following description with reference to the following figures, wherein like reference numerals refer to like parts throughout the various figures unless otherwise specified, and wherein

FIG. 1 is a block diagram schematically illustrating a semiconductor memory device according to an embodiment of the inventive concept.

FIG. 2 is a block diagram schematically illustrating a semiconductor memory device according to another embodiment of the inventive concept.

FIGS. 3 to 5 are block diagrams schematically illustrating an ECC method of a semiconductor memory device of FIG. 1.

FIGS. 6 to 8 are block diagrams schematically illustrating an ECC method of a semiconductor memory device of FIG. 2.

FIG. 9 is a block diagram schematically illustrating a first nonvolatile memory of FIG. 1.

FIG. 10 is a diagram schematically illustrating a memory cell of a first nonvolatile memory of FIG. 9. In FIG. 10, there is assumed that a first nonvolatile memory 110 (refer to FIG. 9) is an MRAM.

FIG. 11 is a block diagram schematically illustrating a second nonvolatile memory of FIG. 1.

FIG. 12 is a flowchart schematically illustrating an ECC method of a semiconductor memory device according to an embodiment of the inventive concept.

FIG. 13 is a flowchart schematically illustrating an ECC method of a semiconductor memory device according to another embodiment of the inventive concept.

### DETAILED DESCRIPTION

Embodiments will be described in detail with reference to the accompanying drawings. The inventive concept, however, may be embodied in various different forms, and should not be construed as being limited only to the illustrated embodiments. Rather, these embodiments are provided as examples so that this disclosure will be thorough and complete, and will fully convey the concept of the inventive concept to those skilled in the art. Accordingly, known processes, elements, and techniques are not described with respect to some of the embodiments of the inventive concept. Unless otherwise noted, like reference numerals denote like elements throughout the attached drawings and written description, and thus descriptions will not be repeated. In the drawings, the sizes and relative sizes of layers and regions may be exaggerated for clarity.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

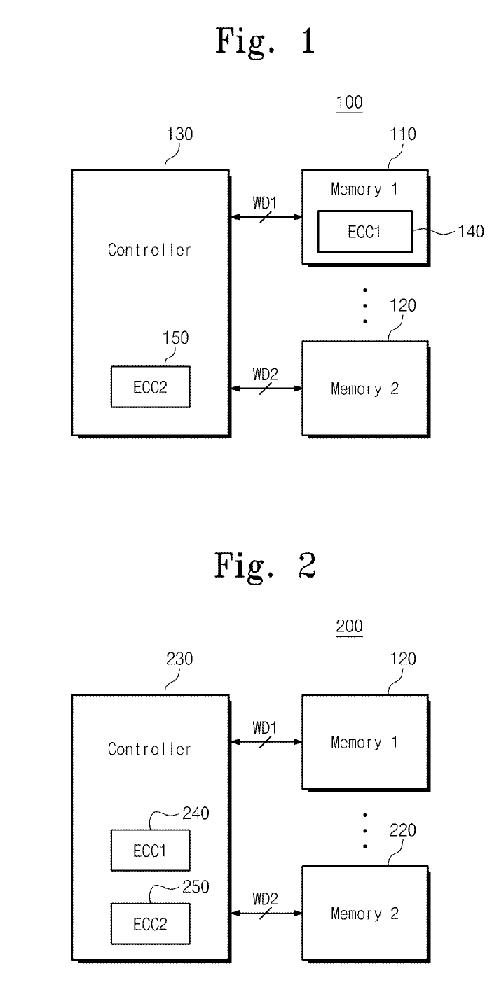

FIG. 1 is a block diagram schematically illustrating a semiconductor memory device according to an embodiment of the inventive concept. Referring to FIG. 1, a semiconductor memory device 100 may include a first nonvolatile memory 110, a second nonvolatile memory 120, a controller 130, a first error correction circuit 140, and a second error correction circuit 150. In FIG. 1, there is illustrated an example in which the semiconductor memory device 100 includes two different types of nonvolatile memories 110 and 120. The semiconductor memory device 100 can further comprise a nonvolatile memory (not shown) which has a type equal to or different from that of the first nonvolatile memory 110 or the second nonvolatile memory 120.

In example embodiments, the first nonvolatile memory 110 may include the first error correction circuit 140 and the controller 130 may include the second error correction circuit 150.

The first nonvolatile memory 110 may receive and store first write data WD1 according to a control of the controller 130. The first nonvolatile memory 110 may generate error correction data for correcting an error of the first write data WD1 using the first error correction circuit 140. Herein, the error correction data may mean ECC data. The first nonvolatile memory 110 may be a specific type of nonvolatile memory. For example, the first nonvolatile memory 110 may be an MRAM.

A type of the second nonvolatile memory 120 may be different from that of the first nonvolatile memory 110. For example, in the event that the first nonvolatile memory 110 is an MRAM, the second nonvolatile memory 120 may be a NAND flash memory. The second nonvolatile memory 120 may receive and store second write data WD2 according to a control of the controller 130. Error correction data for correcting an error of the second write data WD2 may be generated by the second error correction circuit 150.

The controller 130 may control program operations of the first nonvolatile memory 110 and the second nonvolatile memory 120. The controller 130 may include the second error correction circuit 150, and may generate error correction data for correcting an error of the first write data WD1 or the second write data WD2 using the second error correction circuit 150.

The first error correction circuit 140 may be an error correction circuit to correct an error of the first write data WD1. The first error correction circuit 140 may generate error correction data of the first write data WD1 according to a predetermined error correction algorithm. In example embodiments, the error correction algorithm of the first error correction circuit 140 may be an algorithm suitable to process data having a small size and requiring the high reliability. For example, the first error correction circuit 140 may generate error correction data of the first write data WD1 using an error correction algorithm adopting Hamming code.

The second error correction circuit 150 may be used to correct an error of the second write data WD2. For example, the semiconductor memory device 100 may generate error correction data of the second write data WD2 using the second error correction circuit 150.

The second error correction circuit 150 may be selectively used to correct an error of the first write data WD1, based on an attribute of the first write data WD1. Herein, the first write data WD1 may have an attribute of meta data, normal data or buffer data.

The second error correction circuit 150 may generate error correction data of the first write data WD1 or the second write data WD2 according to an error correction algorithm different from that of the first error correction circuit 140. In example embodiments, the error correction algorithm of the second error correction circuit 150 may be an algorithm suitable to process data having a large size and requiring the low reliability. For example, in the event that the second nonvolatile memory 120 is a NAND flash memory, the second error correction circuit 150 may generate error correction data of the first write data WD1 or the second write data WD2 using an error correction algorithm adopting a BCH (Bose-Chaudhuri-Hocquenghem) code or an LDPC (Low-Density Parity-Check) code.

The first write data WD1 may be programmed at the first nonvolatile memory 110 and the second write data WD2 may be programmed at the second nonvolatile memory 120. A minimum program unit of the first nonvolatile memory 110 may be smaller than that of the second nonvolatile memory 120, and the reliability of the first nonvolatile memory 110 may be lower than that of the second nonvolatile memory 120. In example embodiments, the first nonvolatile memory 110 may be a resistive random access memory. The resistive random access memory may be an MRAM, a PRAM, or an RRAM. On the other hand, the second nonvolatile memory 120 may be a NAND flash memory.

The semiconductor memory device 100 may selectively use one of the first error correction circuit 140 and the second error correction circuit 150 according to an attribute of the first write data WD1. For example, if the first write data WD1 is meta data having a small size and requiring the high reliability, the semiconductor memory device 100 may generate error correction data of the first write data WD1 using the first error correction circuit 140 most suitable for the first nonvolatile memory 110. On the other hand, if the first write data WD1 is normal data having a large size and requiring the low reliability, the semiconductor memory device 100 may generate error correction data of the first write data WD1 using the second error correction circuit 150 most suitable to correct an error of mass data.

The semiconductor memory device 100 may generate error correction data of the second write data WD2 using the second error correction circuit 150. Since the second write data WD2 is programmed at the second nonvolatile memory 120 the minimum program unit of which is relatively small and which has the low reliability, error correction data of the second write data WD2 may be generated using the second error correction circuit 150 most suitable to process mass data.

According to embodiments of the inventive concept, a semiconductor memory device including different types of nonvolatile memories may be configured to correct an error of write data selectively using a part of a plurality of error correction circuits to which different error correction algorithms are applied according to an attribute of the write data and a type of nonvolatile memory at which the write data is to be programmed. Thus, error correction may be effectively performed by correcting an error using an error correction algorithm most suitable for an attribute of write data and a type of nonvolatile memory.

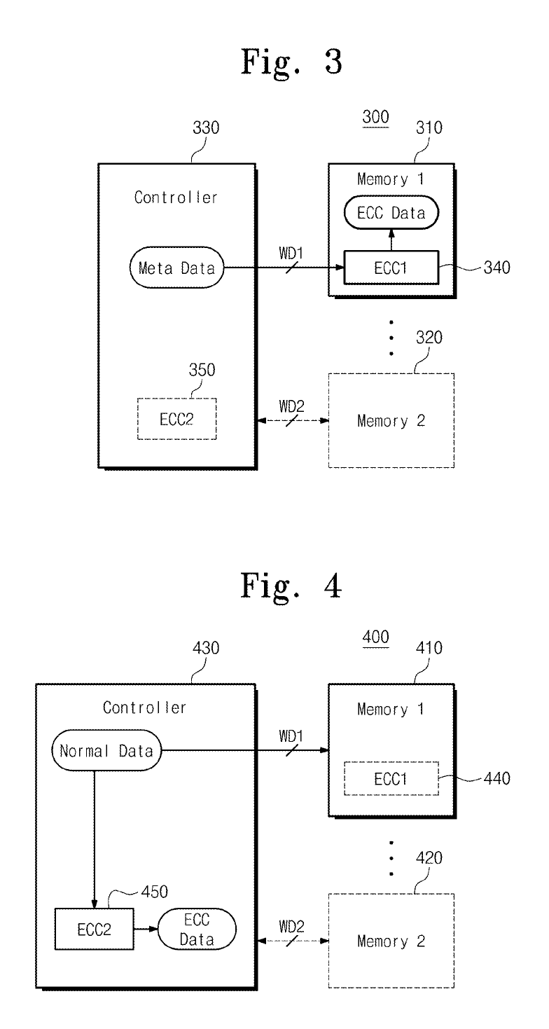

FIG. 2 is a block diagram schematically illustrating a semiconductor memory device according to another embodiment of the inventive concept. Referring to FIG. 2, a semiconductor memory device 200 may include a first nonvolatile memory 210, a second nonvolatile memory 220, a controller 230, a first error correction circuit 240, and a second error correction circuit 250.

In FIG. 2, there is illustrated an example in which the semiconductor memory device 200 includes two different types of nonvolatile memories 210 and 220. However, the inventive concept is not limited thereto. The semiconductor memory device 200 can further comprise a nonvolatile memory (not shown) which has a type equal to or different from that of the first nonvolatile memory 210 or the second nonvolatile memory 220.

In example embodiments, the controller 230 may include both the first error correction circuit 240 and the second error correction circuit 250.

The first nonvolatile memory 210 may receive and store first write data WD1 according to a control of the controller 230. The first nonvolatile memory 210 may be a specific type of nonvolatile memory. For example, the first nonvolatile memory 210 may be an MRAM.

Error correction data for correcting an error of the first write data WD1 may be generated by the first error correction circuit 240 included in the controller 230. The error correction data generated may be stored at a separate register (not shown) included in the first nonvolatile memory 210, the second nonvolatile memory 220 or the controller 230. Herein, the error correction data may mean ECC data.

A type of the second nonvolatile memory 220 may be different from that of the first nonvolatile memory 210. For example, in the event that the first nonvolatile memory 210 is an MRAM, the second nonvolatile memory 220 may be a NAND flash memory. The second nonvolatile memory 220 may receive and store second write data WD2 according to a control of the controller 230. Error correction data for correcting an error of the second write data WD2 may be generated by the second error correction circuit 250. Error correction data for correcting an error of the second write data WD2 may be generated by the second error correction circuit 250, and the error correction data generated may be stored at a separate register (not shown) included in the first nonvolatile memory 210, the second nonvolatile memory 220 or the controller 230.

The controller 230 may control program operations of the first nonvolatile memory 210 and the second nonvolatile memory 220. The controller 230 may include both the first error correction circuit 240 and the second error correction circuit 250, and may generate error correction data for correcting an error of the first write data WD1 or the second write data WD2 using the first error correction circuit 240 or the second error correction circuit 250.

The first error correction circuit 240 may be an error correction circuit to correct an error of the first write data WD1. The first error correction circuit 240 may generate error correction data of the first write data WD1 according to a predetermined error correction algorithm. In example embodiments, the error correction algorithm of the first error correction circuit 240 may be an algorithm suitable to process data having a small size and requiring the high reliability. For example, the first error correction circuit 240 may generate error correction data of the first write data WD1 using an error correction algorithm adopting Hamming code.

The second error correction circuit 250 may be used to correct an error of the second write data WD2. For example, the semiconductor memory device 200 may generate error correction data of the second write data WD2 using the second error correction circuit 250.

The second error correction circuit 250 may be selectively used to correct an error of the first write data WD1, based on an attribute of the first write data WD1. Herein, the first write data WD1 may have an attribute of meta data, normal data or buffer data.

The second error correction circuit 250 may generate error correction data of the first write data WD1 or the second write data WD2 according to an error correction algorithm different from that of the first error correction circuit 240. In example embodiments, the error correction algorithm of the second error correction circuit 250 may be an algorithm suitable to process data having a large size and requiring the low reliability. For example, in the event that the second nonvolatile memory 220 is a NAND flash memory, the second error correction circuit 250 may generate error correction data of the first write data WD1 or the second write data WD2 using an error correction algorithm adopting a BCH (Bose-Chaudhuri-Hocquenghem) code or an LDPC (Low-Density Parity-Check) code.

The first write data WD1 may be programmed at the first nonvolatile memory 210 and the second write data WD2 may be programmed at the second nonvolatile memory 220. A minimum program unit of the first nonvolatile memory 210 may be smaller than that of the second nonvolatile memory 220, and the reliability of the first nonvolatile memory 210 may be lower than that of the second nonvolatile memory 220. In example embodiments, the first nonvolatile memory 210 may be a resistive random access memory. The resistive random access memory may be an MRAM, a PRAM, or an RRAM. On the other hand, the second nonvolatile memory 220 may be a NAND flash memory.

The semiconductor memory device 200 may selectively use one of the first error correction circuit 240 and the second error correction circuit 250 according to an attribute of the first write data WD1. For example, if the first write data WD1 is meta data having a small size and requiring the high reliability, the semiconductor memory device 200 may generate error correction data of the first write data WD1 using the first error correction circuit 240 most suitable for the first nonvolatile memory 110. On the other hand, if the first write data WD1 is normal data having a large size and requiring the low reliability, the semiconductor memory device 200 may generate error correction data of the first write data WD1 using the second error correction circuit 250 most suitable to correct an error of mass data.

The semiconductor memory device 200 may generate error correction data of the second write data WD2 using the second error correction circuit 250. Since the second write data WD2 is programmed at the second nonvolatile memory 220 the minimum program unit of which is relatively small and which has the low reliability, error correction data of the second write data WD2 may be generated using the second error correction circuit 250 most suitable to process mass data.

According to embodiments of the inventive concept, a semiconductor memory device including different types of nonvolatile memories may be configured to correct an error of write data selectively using a part of a plurality of error correction circuits to which different error correction algorithms are applied according to an attribute of the write data and a type of nonvolatile memory at which the write data is to be programmed. Thus, error correction may be effectively performed by correcting an error using an error correction algorithm most suitable for an attribute of write data and a type of nonvolatile memory.

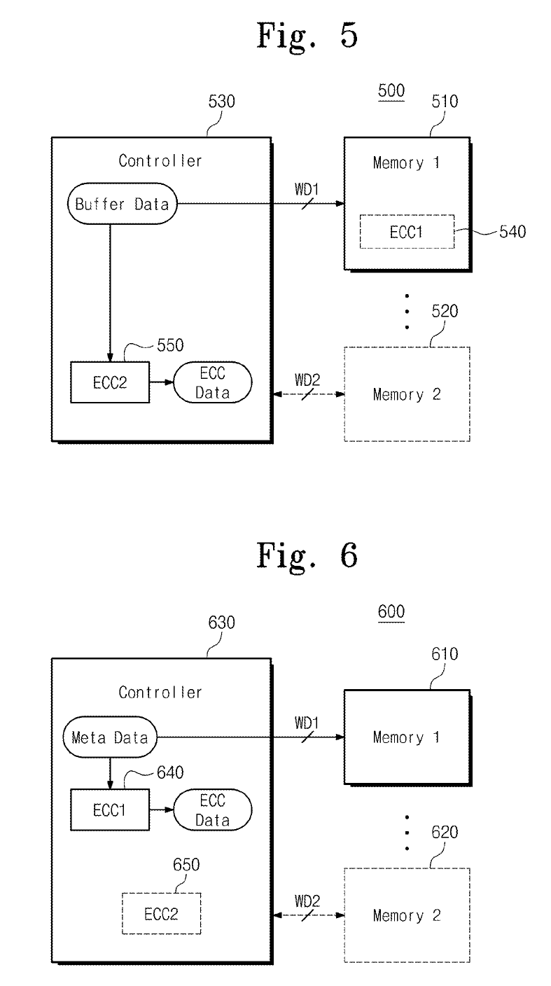

FIGS. 3 to 5 are block diagrams schematically illustrating an ECC method of a semiconductor memory device of FIG. 1. Semiconductor memory devices 300, 400, and 500 illustrated in FIGS. 3 to 5 may be configured substantially the same as a semiconductor memory device 100 of FIG. 1. For example, Referring to FIGS. 3 to 5, first error correction circuit 340, 440, and 540 may be included in first nonvolatile memory 310, 410, and 510, respectively, and second error correction circuit 350, 450, and 550 may be included in controller 330, 430, and 530, respectively.

An ECC method of a semiconductor memory device 300 when first write data WD1 has an attribute of meta data will be described with reference to FIG. 3.

The meta data may have a relatively small size and require the high reliability. The first nonvolatile memory 310 may be suitable to store such data compared with the second nonvolatile memory 320. Thus, in the event that the first write data WD1 is meta data, the semiconductor memory device 300 may transfer the first write data WD1 to the first nonvolatile memory 310, and may control the first nonvolatile memory 310 such that the first error correction circuit 340 generates error correction data of the first write data WD1.

In example embodiments, the error correction data generated by the first error correction circuit 340 may be stored at a separate register (not shown) included in the first nonvolatile memory 310, the second nonvolatile memory 320 or the controller 330.

An ECC method of a semiconductor memory device 400 when first write data WD1 has an attribute of normal data will be described with reference to FIG. 4.

The normal data may have a relatively large size and require the low reliability. The second nonvolatile memory 420 may be suitable to store such data compared with the first nonvolatile memory 410. Thus, in the event that the first write data WD1 is normal data, the semiconductor memory device 400 may control the controller 430 such that the second error correction circuit 450 generates error correction data of the first write data WD1. The controller 430 may transfer the first write data WD1 to the first nonvolatile memory 410, and may control the first nonvolatile memory 410 such that the first write data WD1 is programmed.

In example embodiments, the error correction data generated by the second error correction circuit 450 may be stored at a separate register (not shown) included in the first nonvolatile memory 410, the second nonvolatile memory 420 or the controller 430. In the event that the error correction data is stored at the first nonvolatile memory 410, it may be sent to the first nonvolatile memory 410 together with the first write data WD1.

An ECC method of a semiconductor memory device 500 when first write data WD1 has an attribute of buffer data will be described with reference to FIG. 5.

The buffer data may mean data which is temporarily programmed at the first nonvolatile memory 510 to write it at the second nonvolatile memory 520. In case of the buffer data, it is inefficient to generate error correction data using different error correction circuits when the buffer data is programmed at the first nonvolatile memory 510 and the second nonvolatile memory 520, respectively. In the inventive concept, thus, if the first write data WD1 is buffer data, the semiconductor memory device 500 may generate error correction data of the first write data WD1 using the second error correction circuit 550 most suitable for the second nonvolatile memory 520 when the first write data WD1 is programmed at the first nonvolatile memory 510.

In example embodiments, the error correction data generated by the second error correction circuit 550 may be stored at a separate register (not shown) included in the first nonvolatile memory 510, the second nonvolatile memory 520 or the controller 530. In the event that the error correction data is stored at the first nonvolatile memory 510, it may be sent to the first nonvolatile memory 510 together with the first write data WD1.

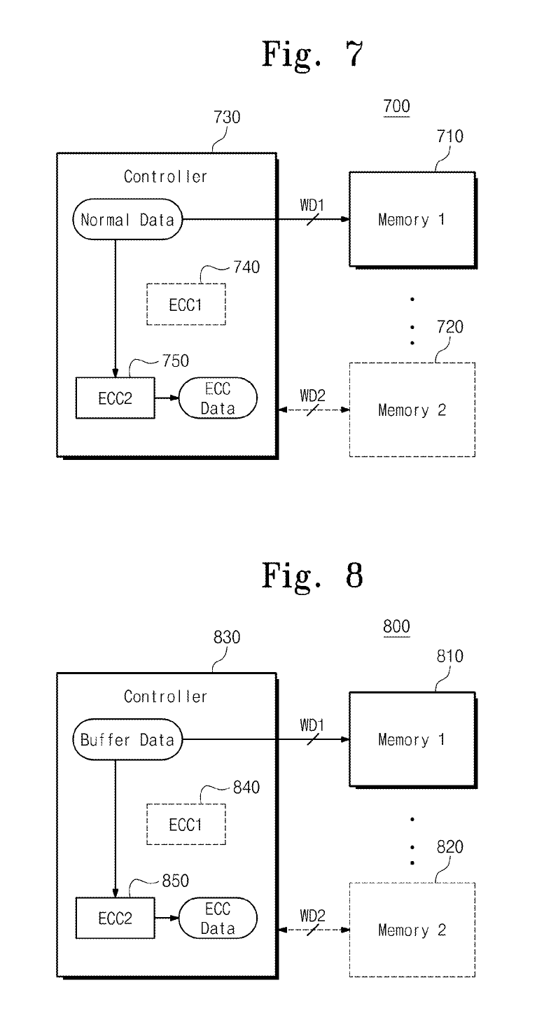

FIGS. 6 to 8 are block diagrams schematically illustrating an ECC method of a semiconductor memory device of FIG. 2. Semiconductor memory devices 600, 700, and 800 illustrated in FIGS. 6 to 8 may be configured substantially the same as a semiconductor memory device 200 of FIG. 2. For example, Referring to FIGS. 6 to 8, first error correction circuit 640, 740, and 840 may be included in first nonvolatile memory 610, 710, and 810, respectively, and second error correction circuit 650, 750, and 850 may be included in controller 630, 730, and 830, respectively.

An ECC method of a semiconductor memory device 600 when first write data WD1 has an attribute of meta data will be described with reference to FIG. 6.

The meta data may have a relatively small size and require the high reliability. The first nonvolatile memory 610 may be suitable to store such data compared with the second nonvolatile memory 620. Thus, in the event that the first write data WD1 is meta data, the semiconductor memory device 600 may transfer the first write data WD1 to the first nonvolatile memory 610, and may control the first nonvolatile memory 610 such that the first error correction circuit 640 generates error correction data of the first write data WD1.

In example embodiments, the error correction data generated by the first error correction circuit 640 may be stored at a separate register (not shown) included in the first nonvolatile memory 610, the second nonvolatile memory 620 or the controller 630.

An ECC method of a semiconductor memory device 700 when first write data WD1 has an attribute of normal data will be described with reference to FIG. 7.

The normal data may have a relatively large size and require the low reliability. The second nonvolatile memory 720 may be suitable to store such data compared with the first nonvolatile memory 710. Thus, in the event that the first write data WD1 is normal data, the semiconductor memory device 700 may control the controller 730 such that the second error correction circuit 750 generates error correction data of the first write data WD1. The controller 730 may transfer the first write data WD1 to the first nonvolatile memory 710, and may control the first nonvolatile memory 710 such that the first write data WD1 is programmed.

In example embodiments, the error correction data generated by the second error correction circuit 750 may be stored at a separate register (not shown) included in the first nonvolatile memory 710, the second nonvolatile memory 720 or the controller 730. In the event that the error correction data is stored at the first nonvolatile memory 710, it may be sent to the first nonvolatile memory 710 together with the first write data WD1.

An ECC method of a semiconductor memory device 800 when first write data WD1 has an attribute of buffer data will be described with reference to FIG. 85.

The buffer data may mean data which is temporarily programmed at the first nonvolatile memory 810 to write it at the second nonvolatile memory 820. In case of the buffer data, it is inefficient to generate error correction data using different error correction circuits when the buffer data is programmed at the first nonvolatile memory 810 and the second nonvolatile memory 820, respectively. In the inventive concept, thus, if the first write data WD1 is buffer data, the semiconductor memory device 800 may generate error correction data of the first write data WD1 using the second error correction circuit 850 most suitable for the second nonvolatile memory 820 when the first write data WD1 is programmed at the first nonvolatile memory 810.

In example embodiments, the error correction data generated by the second error correction circuit 850 may be stored at a separate register (not shown) included in the first nonvolatile memory 810, the second nonvolatile memory 820 or the controller 830. In the event that the error correction data is stored at the first nonvolatile memory 810, it may be sent to the first nonvolatile memory 810 together with the first write data WD1.

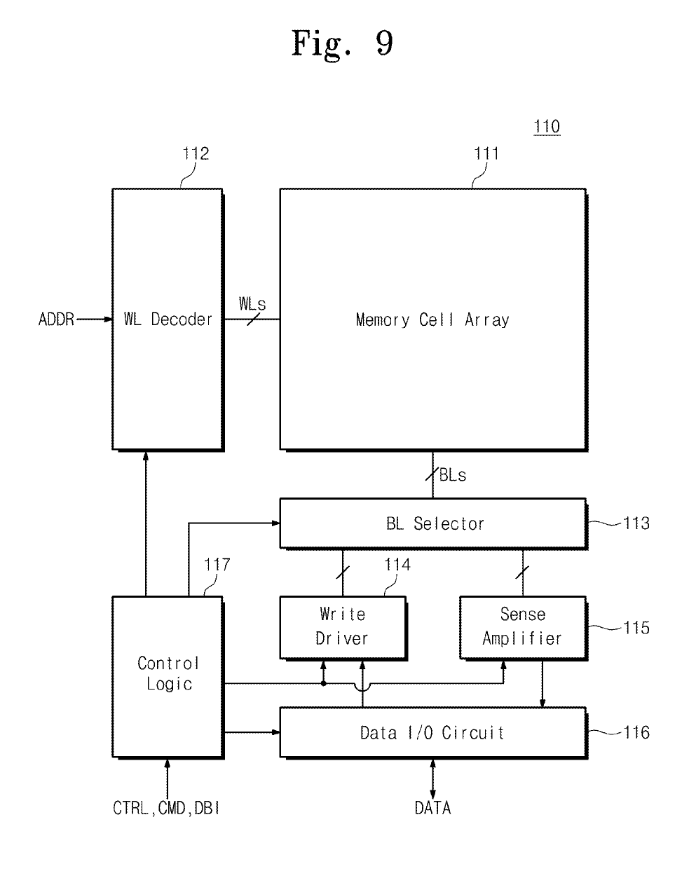

FIG. 9 is a block diagram schematically illustrating a first nonvolatile memory of FIG. 1. In FIG. 9, it is assumed that a first nonvolatile memory 110 is a resistive random access memory. Herein, the resistive random access memory may mean a random access memory which is configured to sense a resistance value between both ends of a memory cell to decide a program state of the memory cell. The resistive random access memory may include an MRAM, a PRAM, a ReRAM, or the like.

Referring to FIG. 9, a nonvolatile memory device 110 may include a memory cell array 111, a word line decoder 112, a bit line selector 113, a write driver 114, a sense amplifier 115, a data input/output circuit 116, and control logic 117.

The memory cell array 111 may be connected with the word line decoder 112 through word lines and with the bit line selector 113 through bit lines. The memory cell array 111 may include a plurality of memory cells. The memory cells in the memory cell array 111 may be resistive memory cells. In example embodiments, memory cells arranged in a row direction may be connected with the word lines. Memory cells arranged in a column direction may be connected with the bit lines. Each of memory cells in the memory cell array 111 may correspond to a word line WL and a bit line BL. Each memory cell may store one or more bits according to voltages or currents applied to the word line WL and the bit line BL.

In example embodiments, the memory cells of the memory cell array 111 may be MRAM cells.

The word line decoder 112 may be connected with the memory cell array 111 through the word lines. The word line decoder 112 may be configured to operate responsive to a control of the control logic 117. The word line decoder 112 may be configured to decode a row address of an address ADDR received from an external device. The word line decoder 112 may select a word line according to the decoded row address.

The bit line selector 113 may be connected with the memory cell array 111 through the bit lines, and may be connected with the write driver 114 and the sense amplifier 115. The bit line selector 113 may select the bit lines in response to a control of the control logic 117. At a program operation, the bit line selector 113 may connect selected bit lines with the write driver 114. At a read operation, the bit line selector 113 may connected selected bit lines with the sense amplifier 115.

The write driver 114 may operate responsive to a control of the control logic 117. The write driver 114 may be configured to program memory cells connected with bit lines selected by the bit line selector 113 and word lines selected by the word line decoder 112. The write driver 114 may generate a set current or a reset current to be provided to selected bit lines, based on data received from the data input/output circuit 1260.

The sense amplifier 115 may operate responsive to a control of the control logic 117. The sense amplifier 115 may be configured to read data from memory cells connected with bit lines selected by the bit line selector 113 and word lines selected by the word line decoder 112. The sense amplifier 115 may read data from memory cells by sensing currents flowing through selected bit lines or voltages applied to the selected bit lines. The sense amplifier 115 may output the read data to the data input/output circuit 116.

The data input/output circuit 116 may operate responsive to a control of the control logic 117. The data input/output circuit 116 may transfer data received from an external device into the sense amplifier 115. The data input/output circuit 116 may output data provided from the sense amplifier 115 to the external device.

The control logic 117 may control an overall operation of the nonvolatile memory device 110. The control logic 117 may operate responsive to a command CMD and a control signal CTRL received from the external device.

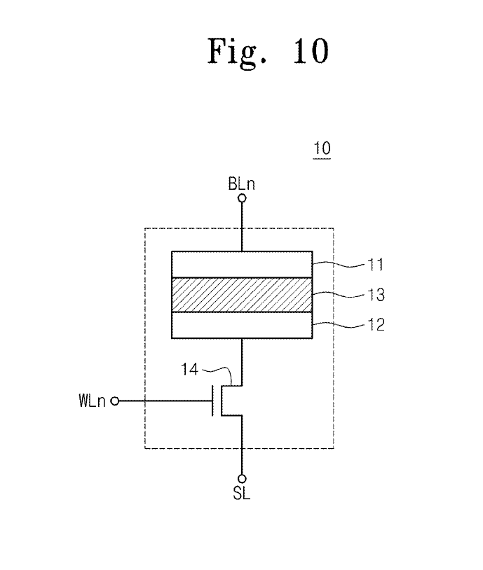

FIG. 10 is a diagram schematically illustrating a memory cell of a first nonvolatile memory of FIG. 9. In FIG. 10, there is assumed that a first nonvolatile memory 110 (refer to FIG. 9) is an MRAM.

A resistance value of a memory cell 10 of the first nonvolatile memory 110 may vary according to a magnetization direction of a magnetic layer included in the memory cell 10. Such a memory cell 10 may be referred to as an MRAM cell. The MRAM cell may be a memory cell which stores a magnetic polarization state at a magnetic thin film, and may perform a write operation by switching a magnetic polarization state by a magnetic field generated according to a bit line current or a word line current.

Referring to FIG. 10, the memory cell 10 may include a switch transistor 14 and a magnetic tunnel junction (MTJ) formed of a pinned magnetic layer 11, a free magnetic layer 12, and a tunnel junction layer 13. Herein, both ends of the memory cell 10 may be connected with one BLn of a plurality of bit lines (refer to FIG. 9) and a source line SL. One WLn of a plurality of word lines (refer to FIG. 9) may be connected with the switch transistor 14 of the memory cell 10, and may select or unselect the memory cell 10.

A thickness of the pinned magnetic layer 11 may be thicker than that of the free magnetic layer 12. A magnetic polarization state of the pinned magnetic layer 11 may be switched when a relatively strong magnetic field is applied. However, a magnetic polarization state of the free magnetic layer 12 can be switched although a relatively weak magnetic field is applied.

The tunnel junction layer 13 may be interposed between the pinned magnetic layer 11 and the free magnetic layer 12. The pinned magnetic layer 11 and the free magnetic layer 12 may have a material such as NiFeCo or CoFe. The tunnel junction layer 13 may have a material such as MgO or AlO3.

The switch transistor 14 may be turned on or off by a voltage of a word line WLn. At a program operation, the memory cell 10 may be selected or unselected by turning the switch transistor 14 on or off. For example, when the switch transistor 14 is turned on, a program current may flow into the memory cell 10. A magnetization direction of the memory cell 10 may vary according to a direction and a level of a program current (or, a program voltage) applied to the bit line BLn.

On the other hand, when the switch transistor 14 is turned off, no program current may flow into the memory cell 10. A magnetization direction of the memory cell 10 may not vary according to a current (or, a voltage) applied to the bit line BLn.

The memory cell 10 having the pinned magnetic layer 11, the tunnel junction layer 13, and the free magnetic layer 12 sequentially stacked may have different electric resistance values according to magnetization directions of the pinned magnetic layer 11 and the free magnetic layer 12. For example, if the magnetization directions of the pinned magnetic layer 11 and the free magnetic layer 12 are equal to each other (or at a parallel state), the memory cell 10 may have a relatively low resistance value. On the other hand, if the magnetization directions of the pinned magnetic layer 11 and the free magnetic layer 12 are contrary to each other (at an anti-parallel state), the memory cell 10 may have a relatively high resistance value.

The first nonvolatile memory 110 (refer to FIG. 9) may decide a program state of the memory cell 10 using such a characteristic that a resistance value of the memory cell 10 varies according to a magnetization direction of the memory cell 10.

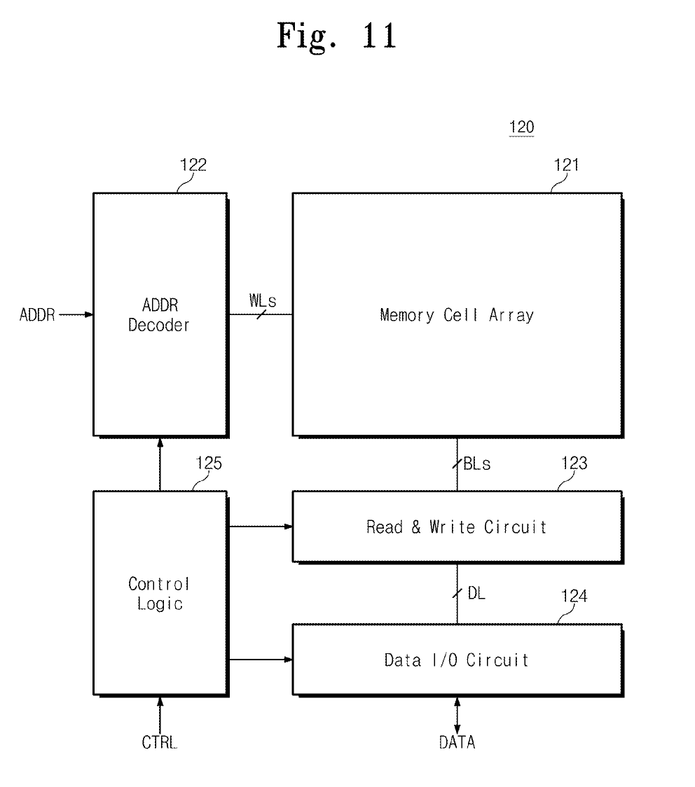

FIG. 11 is a block diagram schematically illustrating a second nonvolatile memory of FIG. 1. In FIG. 11, it is assumed that a second nonvolatile memory 120 is a NAND flash memory.

Referring to FIG. 11, a second nonvolatile memory 120 may include a memory cell array 121, an address decoder 122, a read/write circuit 123, a data input/output circuit 124, and control logic 125.

The memory cell array 121 may be connected to the address decoder 122 through word lines WL and to the read/write circuit 123 through bit lines BL. The memory cell array 121 may include a plurality of memory cells. Memory cells arranged in a row direction may be connected with word lines, and memory cells arranged in a column direction may be connected with bit lines. For example, memory cells arranged in a column direction may form a plurality of cell groups (e.g., strings). The plurality of cell groups may be connected to bit lines, respectively. In example embodiments, each of memory cells may store one or more bits of data.

The address decoder 122 may be connected to the memory cell array 121 through the word lines WL. The address decoder 122 may operate responsive to a control of the control logic 125. The address decoder 122 may receive an address ADDR from an external device.

The address decoder 122 may decode a row address of the input address ADDR, and may select the word lines WL using the decoded row address. The address decoder 122 may decode a column address of the input address ADDR to transfer it to the read/write circuit 123. In example embodiments, the address decoder 122 may include elements such as a row decoder, a column decoder, an address buffer, and so on.

The read/write circuit 123 may be connected to the memory cell array 121 through the bit lines BL. The read/write circuit 123 may be connected to the data input/output circuit 124 through data lines DL. The read/write circuit 123 may operate responsive to a control of the control logic 125. The read/write circuit 123 may select the bit lines BL in response to the decoded column address DCA from the address decoder 122.

In example embodiments, the read/write circuit 123 may receive data from the data input/output circuit 124 to write it in the memory cell array 121. The read/write circuit 123 may read data from the memory cell array 121 to output it to the data input/output circuit 124.

In example embodiments, the read/write circuit 123 may include constituent elements such as a page buffer (or, a page register), a column selecting circuit, a data buffer, and the like. In other example embodiment, the read/write circuit 123 may include constituent elements such as a sense amplifier, a write driver, a column selecting circuit, a data buffer, and the like.

The data input/output circuit 124 may be connected to the read/write circuit 123 through the data lines DL. The data input/output circuit 124 may operate responsive to a control of the control logic 125. The data input/output circuit 124 may be configured to exchange data with an external device. The data input/output circuit 124 may be configured to transfer data provided from the external device to the read/write circuit 123 through the data lines DL. The data input/output circuit 124 may be configured to output data transferred from the read/write circuit 123 through the data lines DL to the external device. In example embodiments, the data input/output circuit 124 may include a constituent element such as a data buffer.

The control logic 125 may be connected with the address decoder 122, the read/write circuit 123, and the data input/output circuit 124. The control logic 150 may be configured to control an overall operation of the second nonvolatile memory device 120. The control logic 125 may operate responsive to a control signal CTRL provided from the external device.

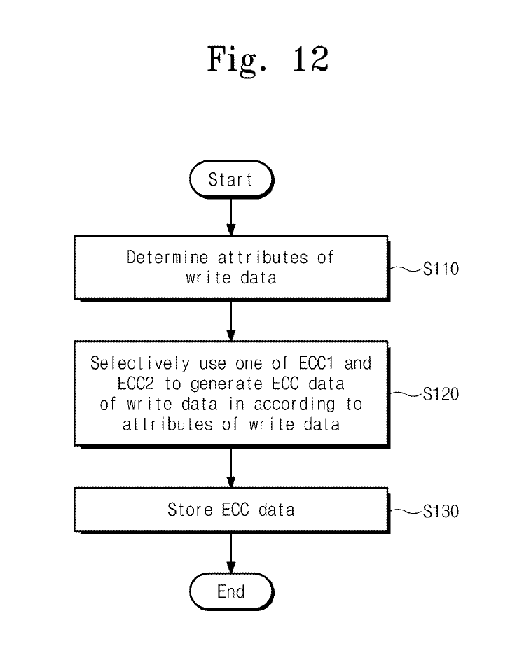

FIG. 12 is a flowchart schematically illustrating an ECC method of a semiconductor memory device according to an embodiment of the inventive concept. Referring to FIG. 12, an ECC method of a semiconductor memory device according to an embodiment of the inventive concept may include operations S110 to S130. Herein, the semiconductor memory device may have the same structure as one of semiconductor memory devices 100, 200, 300, 400, 500, 600, 700, and 800.

In operation S110, the semiconductor memory device may determine an attribute of write data. In example embodiments, the write data may have an attribute of meta data, normal data or buffer data.

In operation S120, the semiconductor memory device may generate error correction data of write data using one of a first error correction circuit and a second error correction circuit according to the attribute of the write data. At this time, the semiconductor memory device may decide a method for generating error correction data in consideration of a type of nonvolatile memory at which the write data is to be stored. Herein, detailed structures of the first error correction circuit and the second error correction circuit and an error correction data generating method of the semiconductor memory device may be substantially the same as described with reference to FIGS. 1 to 8.

In operation S130, the semiconductor memory device may store the error correction data. In example embodiments, the error correction data may be stored at one of nonvolatile memories included in the semiconductor memory device or at a controller to control the nonvolatile memories.

The error correction data thus stored may be used to verify integrity of the write data when the write data is read later.

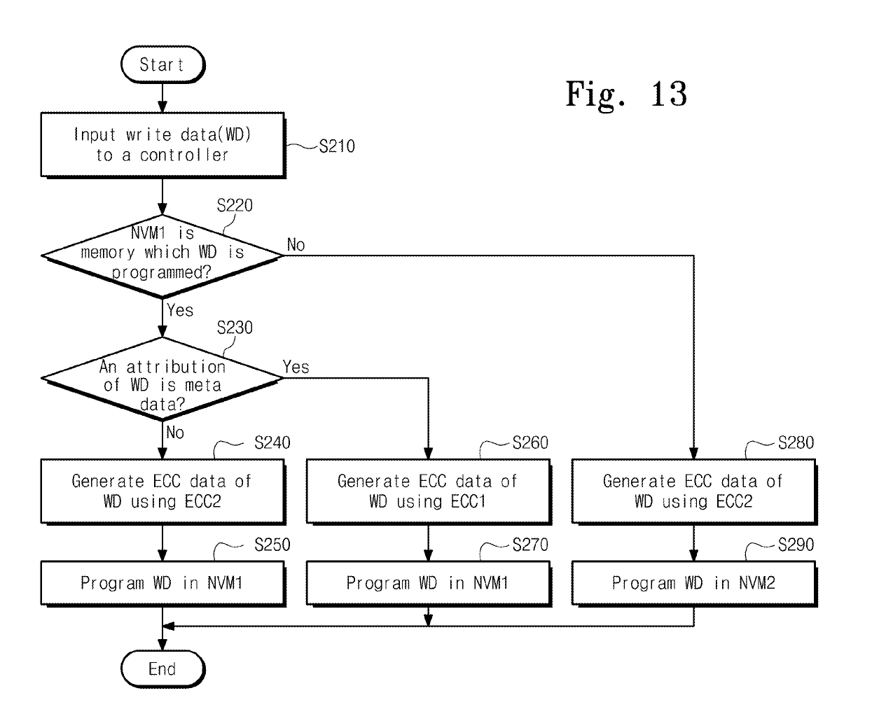

FIG. 13 is a flowchart schematically illustrating an ECC method of a semiconductor memory device according to another embodiment of the inventive concept. Referring to FIG. 13, an ECC method of a semiconductor memory device according to another embodiment of the inventive concept may include operations S210 to 290. Herein, the semiconductor memory device may have the same structure as one of semiconductor memory devices 100, 200, 300, 400, 500, 600, 700, and 800. The semiconductor memory device may include at least two different types of nonvolatile memories, for example, first and second nonvolatile memories NVM1 and NVM2 and a controller to control the first and second nonvolatile memories NVM1 and NVM2. The first nonvolatile memory NVM1 may be configured substantially the same as one of first nonvolatile memories 110, 210, 310, 410, 510, 610, 710, and 810 described with reference to FIGS. 1 to 8. The second nonvolatile memory NVM2 may be configured substantially the same as one of second nonvolatile memories 120, 220, 320, 420, 520, 620, 720, and 820 described with reference to FIGS. 1 to 8. Likewise, the controller may be configured substantially the same as one of controllers 130, 230, 330, 430, 530, 630, 730, and 830 described with reference to FIGS. 1 to 8.

With the ECC method of FIG. 13, error correction data of write data WD may be generated using different error correction circuits according to an attribute of the write data WD and a type of memory at which the write data WD is to be programmed. A reference for selecting an error correction circuit according to an attribute of the write data WD and a type of memory at which the write data WD is to be programmed and an effect may be substantially the same as described with reference to FIGS. 1 to 8.

In operation S210, a semiconductor memory device ma input the write data WD to the controller 130.

In operation S220, the semiconductor memory device may determine whether the write data WD is programmed at any one of the first nonvolatile memory NVM1 and the second nonvolatile memory NVM2. As described above, the first nonvolatile memory NVM1 and the second nonvolatile memory NVM2 may have different types, minimum program units and program speeds. If the first nonvolatile memory NVM1 is determined to be a memory at which the write data WD is to be programmed, the method may proceed to operation S230. If the first nonvolatile memory NVM1 is determined not to be a memory at which the write data WD is to be programmed, the method may proceed to operation S280.

In operation S230, the semiconductor memory device may determine whether the write data WD has an attribute of meta data or an attribute of normal data. If the write data WD is determined to have an attribute of meta data, the method may proceed to operation S260. If the write data WD is determined not to have an attribute of meta data, the method may proceed to operation S240.

In operation S240, since the write data WD does not have an attribute of meta data, the semiconductor memory device may generate error correction data of the write data WD using a second error correction circuit ECC2. Herein, the second error correction circuit ECC2 may be an error correction circuit designed to be suitable for the second nonvolatile memory NVM2. A detailed description on the second error correction circuit ECC2 and a relation with the second nonvolatile memory NVM2 may be substantially the same as described with reference to FIGS. 1 to 8.

In operation S250, the semiconductor memory device may program the write data WD at the first nonvolatile memory NVM1. The semiconductor memory device may store the generated error correction data at the first nonvolatile memory NVM1, the second nonvolatile memory NVM2 or the controller 130 at the same time with programming of the write data WD or before and after programming of the write data WD.

Returning to operation S230, if the write data WD is meta data, the method may proceed to operation S260.

In operation S260, since the write data WD is meta data, the semiconductor memory device may generate error correction data of the write data WD using a first error correction circuit ECC1. Herein, the first error correction circuit ECC1 may be an error correction circuit designed to be suitable for the first nonvolatile memory NVM1. A detailed description on the first error correction circuit ECC1 and a relation with the first nonvolatile memory NVM1 may be substantially the same as described with reference to FIGS. 1 to 8.

In operation S270, the semiconductor memory device may program the write data WD at the first nonvolatile memory NVM1. The semiconductor memory device may store the generated error correction data at the first nonvolatile memory NVM1, the second nonvolatile memory NVM2 or the controller 130 at the same time with programming of the write data WD or before and after programming of the write data WD.

Returning to operation S220, if the first nonvolatile memory NVM1 is not a memory at which the write data WD is to be programmed, that is, if the second nonvolatile memory NVM2 is a memory at which the write data WD is to be programmed, the method may proceed to operation S280.

In operation S280, since the write data WD is data which is programmed at the second nonvolatile memory NVM2, the semiconductor memory device may generate error correction data of the write data WD using the second error correction circuit ECC2 suitable for the second nonvolatile memory NVM2.

In operation S290, the semiconductor memory device may program the write data WD at the second nonvolatile memory NVM2. The semiconductor memory device may store the generated error correction data at the first nonvolatile memory NVM1, the second nonvolatile memory NVM2 or the controller 130 at the same time with programming of the write data WD or before and after programming of the write data WD.

While the inventive concept has been described with reference to exemplary embodiments, it will be apparent to those skilled in the art that various changes and modifications may be made without departing from the spirit and scope of the present invention. Therefore, it should be understood that the above embodiments are not limiting, but illustrative.

1. A semiconductor memory device, comprising:
a first nonvolatile memory;
a second nonvolatile memory having a type different from the first nonvolatile memory;
a controller configured to control the first nonvolatile memory and the second nonvolatile memory;
a first error correction circuit configured to correct an error of first write data to be programmed at the first nonvolatile memory; and
a second error correction circuit included in the controller and configured to correct an error of first write data, or an error of second write data to be programmed at the second nonvolatile memory, based on an error correction algorithm different from that of the first error correction circuit,
wherein error correction data for correcting an error of the first write data is generated using one of the first error correction circuit and the second error correction circuit according to an attribute of the first write data.

2. The semiconductor memory device of claim 1, wherein if the first write data has an attribute of meta data, the error correction data is generated using the first error correction circuit.

3. The semiconductor memory device of claim 1, wherein if the first write data has an attribute of normal data, the error correction data is generated using the second error correction circuit.

4. The semiconductor memory device of claim 1, wherein if the first write data has an attribute of buffer data, the error correction data is generated using the second error correction circuit, and wherein the buffer data is data which is temporarily programmed at the first nonvolatile memory to write the buffer data at the second nonvolatile memory.

5. The semiconductor memory device of claim 1, wherein the first error correction circuit is included in the first nonvolatile memory.

6. The semiconductor memory device of claim 1, wherein the first error correction circuit is included in the controller.

7. The semiconductor memory device of claim 1, wherein a program speed of the first nonvolatile memory is faster than that of the second nonvolatile memory.

8. The semiconductor memory device of claim 1, wherein the first nonvolatile memory is a resistive memory reads a resistance value between both ends of a memory cell to decide data stored at the memory cell.

9. The semiconductor memory device of claim 1, wherein the first nonvolatile memory is a magnetic random access memory.

10. The semiconductor memory device of claim 1, wherein the second nonvolatile memory is a NAND flash memory.

11. The semiconductor memory device of claim 1, wherein the first error correction circuit generates the error correction data according to an error correction algorithm using hamming code.

12. The semiconductor memory device of claim 1, wherein the second error correction circuit generates the error correction data according to an error correction algorithm using a BCH code or an LDPC code.

13. An ECC method of a semiconductor memory device which includes a first nonvolatile memory, a second nonvolatile memory having a type different from that of the first nonvolatile memory, and a controller to control the first nonvolatile memory and the second nonvolatile memory, the ECC method comprising:
determining an attribute of write data to be programmed at the first nonvolatile memory;
generating error correction data for correcting an error of the write data using one of a first error correction circuit and a second error correction circuit according to an attribute of the write data and a type of the first nonvolatile memory; and
storing the error correction data,
wherein the first error correction circuit and the second error correction circuit generate the error correction data according to different error correction algorithms.

14. The ECC method of claim 13, wherein the semiconductor memory device controls the controller such that error correction data for write data to be programmed at the second nonvolatile memory is generated using the second error correction circuit.

15. The ECC method of claim 13, wherein the semiconductor memory device stores the error correction data at the first nonvolatile memory, the second nonvolatile memory or the controller.
